(19) United States
(12) Patent Application Publication
(10) Pub. No.: US 2007/0104292 A1
(43) Pub. Date: May 10, 2007

(54) Timing recovery phase locked loop

(76) Inventor: Peter Gregorius, Munchen (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/267,930

(22) Filed: Nov. 4, 2005

(51) Int. Cl. H03D 3/24

(52) U.S. Cl. 375/327; 375/376

(57) ABSTRACT

Methods and apparatus for timing recovery phase locked loops. One embodiment provides a phase detectors for generating phase difference signals on the basis of a received feedback signal and an input clock signal and an input data signal, respectively. A digital control unit is adapted to generate a control signal depending on the first and second phase difference signals A digitally controlled oscillator generates an output clock signal depending on the control signal. A feedback unit feeds the output clock signal to an input of the first phase detector as the feedback signal. And a data acquisition unit receives the data signal and the output clock signal of the digitally controlled oscillator to provide a data output signal synchronized to the output clock signal.

### BACKGROUND OF THE INVENTION

1. Field of the Invention

The present invention relates to a timing recovery phase locked loop receiving a clock signal and a data signal wherein the data signal is sampled and latched depending on an output clock signal.

2. Description of the Related Art

A timing recovery phase locked loop is designed to generate an output clock signal by which an input data signal can be sampled and/or latched. Usually no input clock signal is initially provided such that the stability of the control loop substantially depends on the data density of the input data signal, i.e. the density of rising and falling edges of the input data signal. This may result in the phase locked loop losing its frequency locking condition if the input data signal contains long periods of time wherein no level transition (edge) occurs. To prevent such an unlocking the input data signal (data stream) is typically coded—the input data signal having a restriction that at least one level transition has to occur within a specific period of time.

Another possibility to overcome this issue is to implement a hold-over mode, i.e. to freeze the frequency of a voltage controlled oscillator of the phase locked loop within a predetermined tolerance. Therefore, in an analog phase locked loop, as conventionally used, a control voltage of the voltage controlled oscillator can be held by a capacity which is, however, expensive to implement. Further, the voltage in the capacity is subjected to leakage, whereby an unlocking of the timing recovery phase locked loop may result.

### SUMMARY OF THE INVENTION

It is therefore an object of the present invention to provide a timing recovery phase locked loop wherein a coding of the input data signal can be avoided and an unlocking of the timing recovery phase locked loop can be avoided or the likelihood thereof can be reduced.

According to a first aspect of the present invention a timing recovery phase locked loop is provided comprising a first phase detector for receiving an input clock signal and a feedback clock signal and for providing a first phase difference signal, a second phase detector for receiving an input data signal and the feedback clock signal and for providing a second phase difference signal, a digital control unit which is adapted to provide a control signal depending on the first and second phase difference signals, a digitally controlled oscillator to provide an output clock signal depending on the control signal, a feedback unit to feedback the output clock signal to an input of the first phase detector as the feedback signal and a data acquisition unit receiving the data signal and the output clock signal of the digitally controlled oscillator to provide a data output signal synchronized to the output clock signal.

The timing recovery phase locked loop has an advantage in that the control loop of the phase locked loop is provided as a digital circuit which helps to avoid the disadvantages of the prior art timing recovery phase locked loops. In other words, the hold-over mode wherein the control voltage of a voltage controlled oscillator is stored by a capacity can be avoided such that all issues related to the provision of such a capacity can be avoided. Furthermore, as the timing recovery phase locked loop according to the present invention receives a clock signal which indicates the data rate of the data signal a coding of the data signal can be avoided.

According to a further aspect of the present invention a timing recovery phase locked loop is provided comprising a digitally controlled oscillator to provide an output clock signal depending on a control signal, a first phase detector for receiving an input clock signal and a divided output clock signal and for providing a first phase difference signal wherein the divided output clock signal is frequency divided by a predetermined division value, a second phase detector for receiving an input data signal and the output clock signal and for providing a second phase difference signal, a digital control unit which is adapted to provide the control signal depending on the first and second phase difference signal, a feedback divider to frequency divide the output clock signal to obtain the divided output clock signal and for providing the divided output clock signal as an input of the first phase detector and a data acquisition unit for receiving the data signal and the output clock signal of the digitally controlled oscillator to provide a data output signal synchronized to the output clock signal.

Such a timing recovery phase locked loop allows synchronization of the data signal to a periodic signal which is indicated by the input clock signal which may have a fraction of the frequency on which the input data signal is based. This allows for an input clock signal having a reduced frequency such that the transmission requirements for the input clock signal are less restrictive.

According to another aspect of the present invention a timing recovery phase locked loop is provided which comprises a first phase detector for receiving an input clock signal and a number of feedback clock signals for providing a set of first phase difference signals, a second phase detector for receiving a input data signal and the number of feedback clock signals and for providing a set of second phase difference signals, a digital control unit which is adapted to provide a control signal depending on the sets of first and second phase difference signals, a digitally controlled oscillator to provide an output clock signal depending on the control signal, a feedback unit to receive the output clock signal and to provide the number of feedback clock signals, wherein each of the number of feedback clock signals has a unique predetermined phase shift, and a data acquisition unit receiving the data signal and the output clock signal to provide a data output signal synchronized to the output clock signal.

According to a further aspect of the present invention a timing recovery phase locked loop is provided which comprises a first phase detector for receiving an input clock signal and a number of feedback clock signals for providing a set of first phase difference signals, a second phase detector for receiving an input data signal and the number of feedback clock signals and for providing a set of second phase difference signals, a digital control unit which is adapted to provide a control signal depending on the sets of the first and the second phase difference signals, a digitally controlled oscillator to provide an output clock signal depending on the control signal, a feedback unit to receive the output clock signal and to provide the number of feedback clock signals, wherein each of the number of feedback clock signals has a unique predetermined phase shift, and a data acquisition unit receiving the data signal and the number of feedback signals to provide a data output signal synchronized to the output signal, wherein the input data signal is sampled by edges of the number of feedback signals.

According to another embodiment of the present invention the control unit may include a loop filter unit.

Furthermore the control unit may include a weighting unit to weight the first and the second phase difference signals depending on a first and second weighting values.

In one embodiment, the control unit may be adapted to set the first and second weighting values depending on a locking condition of the timing recovery phase locked loop. Thereby, it may be possible, that the control unit first controls the weighting values such that the phase locked loop is locked onto the frequency of the clock signal whereby after locking the phase locked loop onto the frequency indicated by the input clock signal the weighting values are changed such that the control signal is provided mainly depending on the second phase difference signal.

According to another embodiment of the present invention the control unit includes an adder unit which is adapted to add the weighted first and second phase difference signals.

A frequency detector may be provided to supply a frequency difference signal to the control unit wherein the frequency difference signal indicates a frequency difference between the output clock signal and the input clock signal.

The control unit may further include a further weighting unit to provide a weighting of a frequency difference signal. Accordingly, the adder unit may be adapted to further add the weighted frequency difference signal to obtain the control signal.

According to another embodiment of the present invention the feedback unit comprises a frequency divider to set a multiplication factor for the case that the input clock signal has a frequency which is different from the frequency the data rate of the data signal is based on. Furthermore the feedback unit may comprise a frequency multiplier which may allow in combination with the frequency divider to realize fractional multiplication factors to adapt the frequency of the input clock signal to the frequency of the data rate the data signal is based on.

According to another embodiment of the present invention a timing recovery phase locked loop is provided comprising a first decimator unit coupled between the first phase detector and the control unit to parallelize the first phase difference signal and to reduce its frequency and a second decimator unit coupled between the second phase detector and the control unit to parallelize the second phase difference signal and to reduce its frequency. The provision of the decimator unit has the advantage that the frequency within the control loop of the phase locked loop can be reduced which facilitates the electronic circuit design of such a digital control loop.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a conventional timing recovery phase locked loop for restoring a clock signal from an input data signal;

FIG. 2 is a block diagram of a timing recovery phase locked loop according to a first embodiment of the present invention;

FIG. 3 is a block diagram of a timing recovery phase locked loop according to a second embodiment of the present invention;

FIG. 4 is a block diagram of a timing recovery phase locked loop according to a third embodiment of the present invention;

FIG. 5 is a block diagram of a timing recovery phase locked loop according to a fourth embodiment of the present invention;

FIG. 6 is a block diagram of a timing recovery phase locked loop according to a fifth embodiment of the present invention; and

FIG. 7 is a block diagram of a timing recovery phase locked loop according to a sixth embodiment of the present invention.

### DETAILED DESCRIPTION OF THE PREFERRED EMBODIMENT

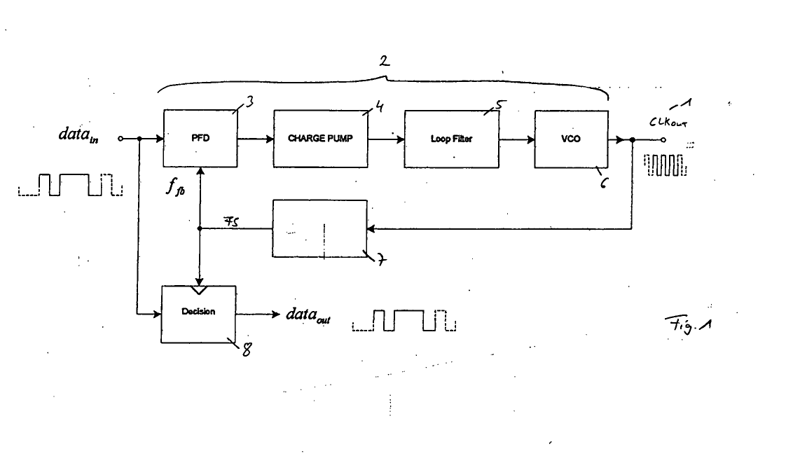

FIG. 1 shows a block diagram of a timing recovery phase locked loop 1 having one data input for receiving an input data signal DATAᵢₙ to synchronize the input data signal DATAᵢₙ with a generated output clock signal CLKₒᵤₜ. The incoming data stream is substantial because no reference clock signal is provided. Therefore, a control loop 2 of the phase locked loop 1 depends on the data density of the input data signal DATAᵢₙ which means that level transitions of the input data signal DATAᵢₙ have to occur regularly such that the phase locked loop 1 can maintain the frequency of the clock signal the input data signal DATAᵢₙ is based on. Otherwise, such a phase locked loop may unlock if the input data signal DATAᵢₙ comprises a series of data bits without the occurrence of level transitions. To avoid this in conventional systems a coding of the input data signal is required. Another possibility to prevent an unlocking lies in the implementing of a hold-over mode wherein the frequency of the oscillator is locked within a tolerance range while no level transitions occur. Usually, in the “hold-over” mode the locking of the frequency is performed by providing a capacity for storing the control voltage of the voltage controlled oscillator. This, however, is expensive in area and an unlocking of the timing recovery is not securely prevented.

In detail the timing recovery phase locked loop 1 of FIG. 1 shows the control loop 2 including a phase/frequency detector 3, a charge pump circuit 4, a loop filter 5 and a voltage controlled oscillator 6. An output of the voltage controlled oscillator is fed back via a feedback unit 7 to one input of the phase/frequency detector 3. Another input of the phase frequency detector 3 receives the input data signal DATAᵢₙ and generates a pulse code modulated phase difference signal which is fed to the charge pump circuit 4. The charge pump circuit 4 generates an output current which is filtered in the loop filter 5 and stored, e.g. in a capacity when such a control voltage can be applied to the voltage controlled oscillator 6. The feedback unit 7 may include a feedback divider to divide the frequency of an output clock signal CLKₒᵤₜ to obtain a feedback signal FS for feeding back to the phase frequency detector 3. The feedback signal FS supplied by the feedback unit 7 is also supplied to a clock input of a latch 8 on the data input of which the input data signal DATAᵢₙ is applied. In the locked condition of the phase locked loop the output clock signal CLKₒᵤₜ is synchronous to the input data signal DATAᵢₙ such that the input data signal DATAᵢₙ can be latched in the latch 8 which further provides an output data signal DATAₒᵤₜ which is synchronous to the output clock signal CLKₒᵤₜ.

In the following, timing recovery phase locked loops having an input for the input data signal and an input for an input clock signal which gives an indication of the clock signal to which the output data signal should be synchronized. In all embodiments the reference signs T, U, V, W, X, Y, Z indicate the numbers of parallel signal lines.

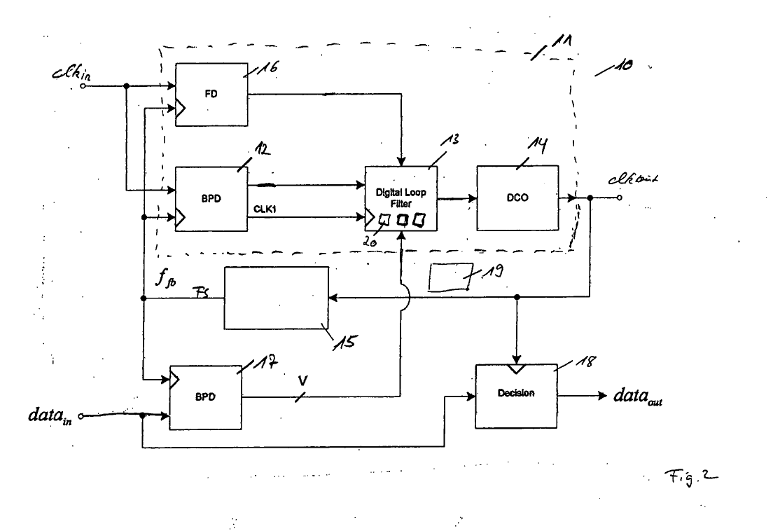

According to the first embodiment of the present invention, FIG. 2 shows a timing recovery phase locked loop 10 which comprises a control loop which is implemented as digital circuits. The control loop 11 comprises a first phase detector 12 which receives an input clock signal CLKᵢₙ on one input and a feedback signal FS on a further input. The first phase detector 12 generates a phase difference signal which is supplied to a digital loop filter 13. The digital loop filter 13 generates a digital control value which is forwarded to a digitally controlled oscillator 14 which supplies an output clock signal CLKₒᵤₜ the frequency of which is depending on the digital control value. The output clock signal CLKₒᵤₜ is fed back via a feedback unit 15 as the feedback signal FS to the phase detector 12. Furthermore, a frequency detector 16 may be included in the control loop 11 which receives the input clock signal CLKᵢₙ and the feedback signal FS from the feedback unit 15. The frequency detector 16 compares the frequency of the input clock signal CLKᵢₙ and the frequency of the feedback signal FS and supplies the result as a frequency difference signal to the digital loop filter 13.

A second phase detector 17 is provided which receives on one input the input data signal DATAᵢₙ and on a further input a feedback signal FS. The second phase detector 17 provides a second phase difference signal to the digital loop filter 13.

The digital loop filter 13 outputs the digital control value depending on the first and second phase difference signals as well as on the frequency difference signal. Furthermore, a latch 18 is provided which receives the input data signal DATAᵢₙ on one input and the output clock signal CLKₒᵤₜ on a clock input. As the output clock signal CLKₒᵤₜ is synchronized to the input data signal DATAᵢₙ on an output of the latch 18 an output data signal can be tapped which is synchronous to the output clock signal CLKₒᵤₜ.

By the provision of the control loop 11 as a digital control loop a hold-over mode is much simpler to implement because the control value has to be stored instead of storing an analog voltage when using an analog control loop.

The timing recovery phase locked loop of the embodiment of FIG. 2 applies especially for meso-synchronous or source-synchronous systems wherein a reference clock signal is provided besides the data signal. It has an advantage that the timing recovery phase locked loop uses the frequency information of the input clock signal CLKᵢₙ for locking the frequency of the output clock signal CLKₒᵤₜ such that the synchronization of the timing recovery phase locked loop onto the frequency can be easily carried out. In particular, the locking of the frequency is performed by the frequency detector 16. The frequency difference signal output therefore is mainly considered during the locking condition of the phase locked loop.

The phase of the incoming data stream is then compared with the feedback signal FS which is already synchronized in frequency.

A control unit 19 is provided which controls weighting units 20 which are included in the digital loop filter 13 and which provides a weighting of the frequency difference signal, of the first phase difference signal and of the second phase difference signal with respective weighting values. The weighted difference signals are then added and latched to provide the digital control value to the digitally controlled oscillator 14.

In a source synchronous system the input clock signal and the data stream (input data signal) are correlated. In an initial condition of the timing recovery phase locked loop 10, the control unit 19 may control the weighting units 20 such that the first phase difference signal is weighted by a higher weighting factor than the second phase difference signal while in a steady state of the timing recovery phase locked loop 10 the phase information (second phase difference signal) of the data stream can be weighted by a higher weighting factor than the first phase difference signal.

The control unit 19 may include a finite state machine which detects the steady state depending on the frequency and phase difference signal, as well as a missing of the data stream and/or the input clock signal. This may be important, if the connection to the data source is interrupted.

The control unit 19 may be controlled from an external source. Furthermore, the control unit may decrease the weighting factor of the weighting unit 20 for the first phase difference signal to zero such that the first phase detector 12 is effectively switched off. This maybe advantageous on occurrence of an input data signal having a low number of level transitions wherein the timing recovery phase locked loop 10 would be controlled by the first phase difference signal as the second phase difference signal cannot be generated. In case that the input clock signal has a low correlation to the input data signal the synchronization between the data signal and the output clock signal would be lost.

In the embodiments described below same reference signs indicate elements having the same or similar functions.

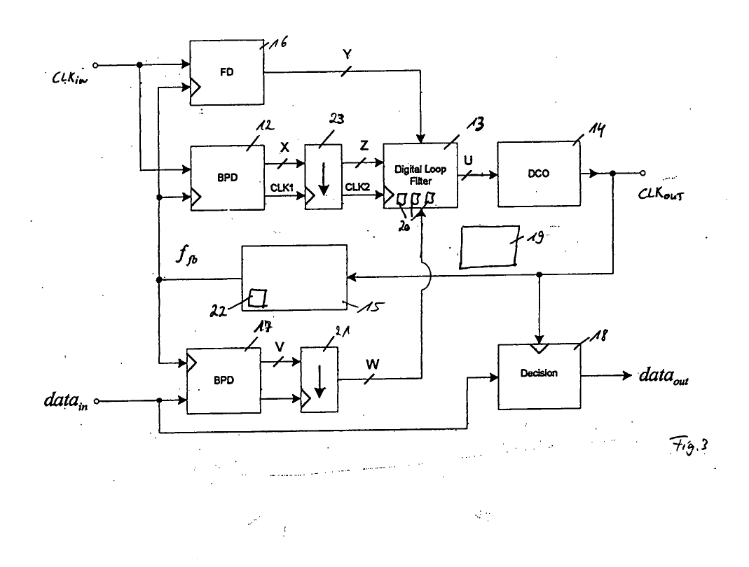

The embodiment of FIG. 3 differs from the embodiment of FIG. 2 in that between the first phase detector 12 and the digital loop filter 13 a first decimator unit 23 is provided which decreases the data rate of the first phase difference signal by parallelizing the data. A second decimator unit 21 is provided to receive the second phase difference signal from the second phase detector 17 and to output a parallelized second phase difference signal to the digital loop filter 13 having a lower data rate than is output by the second phase detector 17. The provision of the decimator units 23, 21 allows to decrease the frequency in the control loop 11 of the timing recovery phase locked loop 10 such that the requirements to the digital circuits of the control loop can be reduced. The decimator factors set in the decimator units 20, 21 depend on the frequency of the input clock signal and on the frequency the data rate of the input data signal stream is based on in the event that the frequency of the input clock signal and the base frequency of the input data stream are not equal.

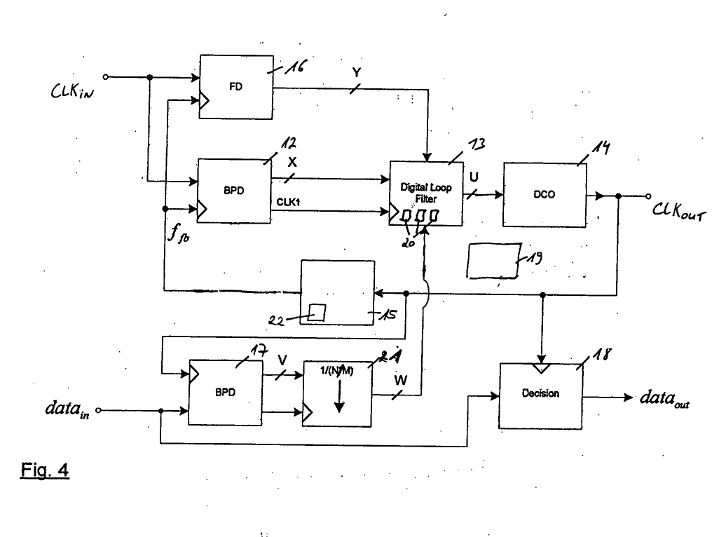

In FIG. 4 another embodiment of a timing recovery phase locked loop is shown wherein the feedback unit 15 comprises a feedback divider 22 to provide a fractional factor which corresponds to the factor the frequency of the input clock signal is reduced with regard to the base frequency of the input data signal DATAᵢₙ. In contrast to the embodiment to FIG. 2 the feedback signal FS output by the feedback unit 15 is fed back to the frequency detector 16 and the first phase detector 12 wherein instead of the feedback signal FS the output clock signal CLKₒᵤₜ is coupled to the respective input of the second phase detector 17. This allows that the input data signal DATAᵢₙ is sampled by the frequency of the output clock signal which is higher than the frequency of the feedback signal FS, namely by the factor N/M. To adapt the frequency of the second phase difference signal output by the second phase detector 17 a second decimator unit 21 as already described with regard to the embodiment of FIG. 3 is arranged between the second phase detector 17 and the digital loop filter 13. The second decimator unit 21 is set that the data rate of the second phase difference signal is reduced by the factor N/M which preferably equals the fractional factor set in the frequency divider 22 of the feedback unit 15.

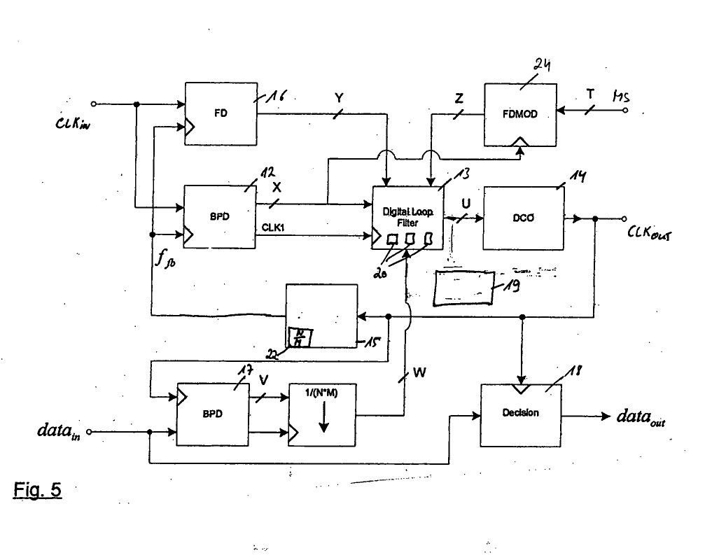

FIG. 5 shows a block diagram of another embodiment of the present invention based on the embodiment as shown in FIG. 4. The embodiment of FIG. 5 differs from the embodiment of FIG. 4 in the provision of a modulation unit 24 which receives a modulation signal MS having a modulation frequency and which is connected with the digital loop filter 13. The modulation unit 24 serves for modulating the clock of the timing recovery phase locked loop which may especially be useful for systems having a spread spectrum clocking (SSC). In such an embodiment, the frequency of the timing recovery phase locked loop is modulated in frequency for reducing electromagnetic interferences. For instance, this can be used in computer systems in the fields of SATA, advanced memory buffer, etc.

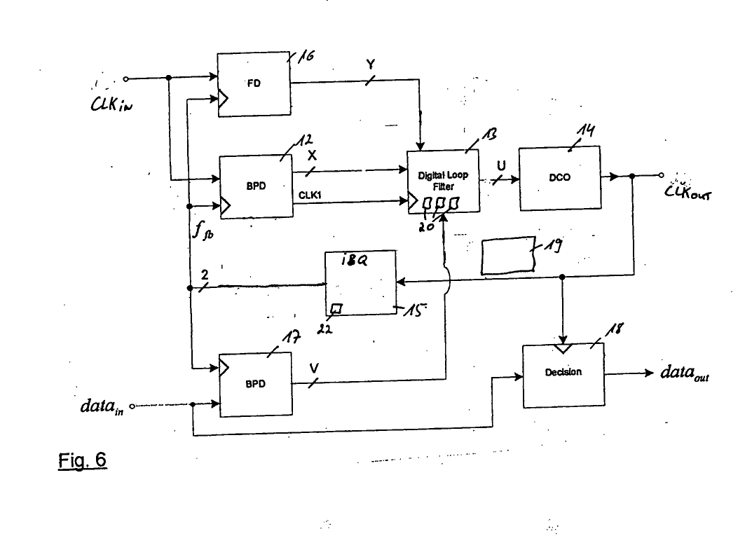

In FIG. 6 another embodiment of the present invention is illustrated which is similar to the embodiment of FIG. 2. The embodiment of FIG. 6 differs from the embodiment of FIG. 2 in that the feedback unit 15 generates a number of feedback signals—preferably two feedback signals—one of which is in phase and one of which is in quadrature phase with regard to one of the output signal and the frequency divided output clock signal. The number of feedback signals FS is applied to the first and second phase detectors and the frequency detector. The first and second phase detectors 12, 17 are designed to sample the input clock signal and the input data signal DATAᵢₙ with regard to each of the number of feedback signals, respectively, such that a set of first and second phase difference signals is obtained, respectively. By using two feedback signals FS (instead of one) which have a predetermined phase shift, it is possible to oversample the input clock signal CLKᵢₙ and the input data signal DATAᵢₙ in the phase detectors 12, 17 such that a better discrimination of the phase differences between the respective input signal and the feedback signal FS can be achieved. This set of first and second phase difference signals is supplied to the digital loop filter 13 wherein a weighting factor is provided for each of the phase difference signals of the sets of first and second phase difference signals, e.g. by means of the control unit 19 which allows for a faster and more secure locking of the phase locked loop.

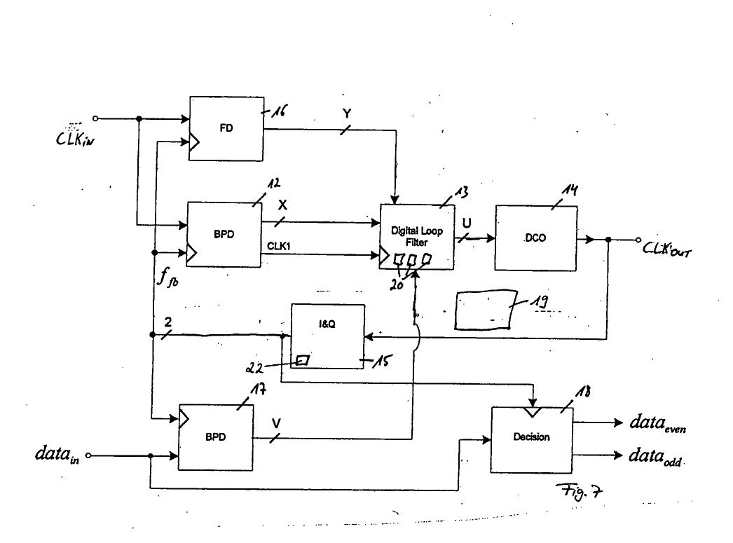

In FIG. 7 another embodiment of the present invention is illustrated which uses the number of feedback signals for sampling of the incoming data stream (input data signal) such that the input data signal is sampled in the latch 18 by a half-clock method (even and odd) such that the symbols are sampled with the rising (or falling) edges of the feedback signals, respectively. Thereby, the incoming data stream can be synchronized to an output clock signal and adapted to a half-symbol rate, simultaneously. By using the rising and falling edges of the feedback signals a one-forth-ratio-clock system is provided.

While the foregoing is directed to embodiments of the present invention, other and further embodiments of the invention may be devised without departing from the basic scope thereof, and the scope thereof is determined by the claims that follow.

What is claimed is:

1. A timing recovery phase locked loop, comprising:
a first phase detector for receiving an input clock signal and a feedback signal and for providing a first phase difference signal;
a second phase detector for receiving an input data signal and the feedback signal and for providing a second phase difference signal;
a digital control unit configured to provide a control signal depending on the first and second phase difference signals;
a digitally controlled oscillator configured to provide an output clock signal depending on the control signal;
a feedback unit to feed back the output clock signal to an input of the first phase detector as the feedback signal;
a data acquisition unit configured to receive the input data signal and the output clock signal of the digitally controlled oscillator and to generate a data output signal synchronized to the output clock signal.

2. The timing recovery phase locked loop of claim 1, wherein the feedback unit comprises a frequency divider.

3. The timing recovery phase locked loop of claim 2, wherein the feedback unit further comprises a frequency multiplier.

4. The timing recovery phase locked loop of claim 1, further comprising:
a first decimator unit coupled between the first phase detector and the control unit to parallelize the first phase difference signal and to reduce its frequency; and
a second decimator unit coupled between the second phase detector and the control unit to parallelize the second phase difference signal and to reduce its frequency.

5. The timing recovery phase locked loop of claim 1, wherein the control unit includes a loop filter unit.

6. The timing recovery phase locked loop of claim 1, wherein the control unit includes a weighting unit to weight the first and the second phase difference signals according to a first and second weighting values, respectively.

7. The timing recovery phase locked loop of claim 6, wherein the control unit is adapted to set the first and second weighting values depending on a locking condition of the timing recovery phase locked loop.

8. The timing recovery phase locked loop of claim 6, wherein the control unit includes an adder unit adapted to add the weighted first and second phase difference signals.

9. The timing recovery phase locked loop of claim 8, further comprising a frequency detector to supply a frequency difference signal to the control unit, wherein the frequency difference signal indicates the frequency difference between the output clock signal and the input clock signal.

10. The timing recovery phase locked loop of claim 9, wherein the control unit includes a further weighting unit to provide a weighting of the frequency difference signal.

11. The timing recovery phase locked loop of claim 10, wherein the adder unit is adapted to further add the weighted frequency difference signal.

12. A method for operating a timing recovery phase locked loop, comprising:
receiving, by a first phase detector, an input clock signal and a feedback signal;
on the basis of the input clock signal and a feedback signal, generating, by the first phase detector, a first phase difference signal;
receiving, by a second phase detector, an input data signal and the feedback signal;
on the basis of the input data signal and the feedback signal, generating, by the second phase detector, a second phase difference signal;
generating a control signal depending on the first and second phase difference signals;
generating, by a digitally controlled oscillator, an output clock signal depending on the control signal;
feeding back the output clock signal to an input of the first phase detector as the feedback signal; and
responsive to receiving the input data signal and the output clock signal of the digitally controlled oscillator, generating a data output signal synchronized to the output clock signal.

13. The method of claim 12, further comprising:
weighting the first and the second phase difference signals with first and second weighting values, respectively; and
adding the weighted first and second phase difference signals.

14. The method of claim 12, further comprising:
supplying a frequency difference signal to a control unit which generates the control signal, wherein the frequency difference signal indicates the frequency difference between the output clock signal and the input clock signal;
weighting the frequency difference signal; and
adding the weighted frequency difference signal, the adding of the weighted frequency difference signal being done by an adder also performing the adding of the weighted first and second phase difference signals.

15. A timing recovery phase locked loop, comprising:
a digitally controlled oscillator to provide an output clock signal depending on a control signal;
a first phase detector for receiving an input clock signal and a divided output clock signal and for providing a first phase difference signal, wherein the output clock signal is frequency divided by a predetermined division value;
a second phase detector for receiving an input data signal and the divided output clock signal and for providing a second phase difference signal;
a digital control unit which adapted to provide the control signal depending on the first and second phase difference signals;
a feedback divider to frequency divide the output clock signal to generate the divided output clock signal and for providing the divided output clock signal as an input of the first phase detector; and
a data acquisition unit receiving the input data signal and the output clock signal of the digitally controlled oscillator to generate a data output signal synchronized to the output clock signal.

16. The timing recovery phase locked loop of claim 15, wherein the control unit includes a loop filter unit.

17. The timing recovery phase locked loop of claim 15, further comprising:
a first decimator unit coupled between the first phase detector and the control unit to parallelize the first phase difference signal and to reduce its frequency; and
a second decimator unit coupled between the second phase detector and the control unit to parallelize the second phase difference signal and to reduce its frequency.

18. The timing recovery phase locked loop of claim 15, wherein the control unit includes a weighting unit to weight the first and the second phase difference signals according to first and second weighting values, respectively.

19. The timing recovery phase locked loop of claim 18, wherein the control unit is adapted to set the first and second weighting values depending on a locking condition of the timing recovery phase locked loop.

20. The timing recovery phase locked loop of claim 19, wherein the control unit includes an adder unit adapted to add the weighted first and second phase difference signals.

21. The timing recovery phase locked loop of claim 20, further comprising a frequency detector to supply a frequency difference signal to the control unit, wherein the frequency difference signal indicates the frequency difference between the output clock signal and the input clock signal.

22. The timing recovery phase locked loop of claim 21, wherein the control unit includes a weighting unit to provide a weighting of the frequency difference signal.

23. The timing recovery phase locked loop of claim 22, wherein the adder unit is adapted to further add the weighted frequency difference signal.

24. A timing recovery phase locked loop, comprising:
a first phase detector for receiving an input clock signal and a number of feedback clock signals for providing a set of first phase difference signals;
a second phase detector for receiving an input data signal and the number of feedback clock signals and for providing a set of second phase difference signals;
a digital control unit adapted to provide a control signal depending on the sets of first and second phase difference signals;
a digitally controlled oscillator to provide an output clock signal depending on the control signal;
a feedback unit to receive the output clock signal and to provide the number of feedback clock signals, wherein each of the number of feedback clock signals has a unique predetermined phase shift; and
a data acquisition unit receiving the input data signal and the output clock signal to provide a data output signal synchronized to the output clock signal.

25. The timing recovery phase locked loop of claim 24, wherein the control unit includes a loop filter unit.

26. The timing recovery phase locked loop of claim 24, further comprising:
a first decimator unit coupled between the first phase detector and the control unit to parallelize the first phase difference signal and to reduce its frequency; and
a second decimator unit coupled between the second phase detector and the control unit to parallelize the second phase difference signal and to reduce its frequency.

27. The timing recovery phase locked loop of claim 24, wherein the control unit includes a weighting unit to weight the first and the second phase difference signals with first and second weighting values, respectively.

28. The timing recovery phase locked loop of claim 27, wherein the control unit is adapted to set the first and second weighting values depending on a locking condition of the timing recovery phase locked loop.

29. The timing recovery phase locked loop of claim 27, wherein the control unit includes an adder unit adapted to add the weighted first and second phase difference signals.

30. The timing recovery phase locked loop of claim 29, further comprising a frequency detector configured to supply a frequency difference signal to the control unit, wherein the frequency difference signal indicates the frequency difference between the output clock signal and the input clock signal.

31. The timing recovery phase locked loop of claim 30, wherein the feedback unit further comprises a frequency multiplier.

32. The timing recovery phase locked loop of claim 30, wherein the control unit includes a weighting unit to provide a weighting of the frequency difference signal.

33. The timing recovery phase locked loop of claim 32, wherein the adder unit is adapted to further add the weighted frequency difference signal.

34. A timing recovery phase locked loop, comprising:
a first phase detector for receiving an input clock signal and a number of feedback clock signals and configured to generate a set of first phase difference signals;
a second phase detector for receiving an input data signal and the set of feedback clock signals and configured to generate a set of second phase difference signals;
a digital control unit adapted to generate a control signal depending on the sets of first and second phase difference signals;
digitally controlled oscillator to generate an output clock signal depending on the control signal;
a feedback unit to receive the output clock signal and to generate the number of feedback clock signals, wherein each of the number of feedback clock signals has a unique predetermined phase shift; and
a data acquisition unit receiving the data signal and the number of feedback signals to provide a data output signal synchronized to the output clock signal, wherein the input data signal is sampled by edges of the number of feedback signals.
